(19) United States
(12) Patent Application Publication
(10) Pub. No.: US 2024/0128158 A1
(43) Pub. Date: Apr. 18, 2024

(54) TSV-BUMP STRUCTURE, SEMICONDUCTOR DEVICE, AND METHOD OF FORMING THE SAME

(71) Applicant: Micron Technology, Inc., Boise, ID (US)

(72) Inventors: YUTAKA NAKAE, Hiroshima (JP); NOBUYUKI NAKAMURA, Hiroshima (JP)

(73) Assignee: Micron Technology, Inc., Boise, ID (US)

(21) Appl. No.: 18/046,650

(22) Filed: Oct. 14, 2022

(51) Int. Cl. H01L 23/48; H01L 21/306; H01L 21/324; H01L 21/48; H01L 23/00

(52) U.S. Cl. CPC H01L 23/481; H01L 21/306; H01L 21/324; H01L 21/486; H01L 24/11; H01L 24/13; H01L 2224/11502; H01L 2224/13009; H01L 2224/13025

(57) ABSTRACT

According to one or more embodiments of the disclosure, a through-silicon via (TSV)-Bump structure is provide. The TSV-Bump structure comprises a TSV in a semiconductor substrate and a bump on the TSV. The bump includes a conductive plug portion and a step structure portion under the conductive plug portion. The step structure is configured to electrically couple the TSV and the conductive plug portion with each other.

### BACKGROUND

A semiconductor system may include a plurality of semiconductor devices stacked on each other to form, for example, a three-dimensional integrated circuit or a three-dimensional semiconductor chip package. The stacked semiconductor devices may be electrically connected to each other by through-silicon vias (hereinafter referred to as “TSVs”). The TSVs are vertical electrical connections that extend through a semiconductor substrate, such as a silicon wafer or die. There may also be provided conductive bumps on the respective TSVs to electrically connect the TSVs with contact electrodes, wirings, or the like of the semiconductor devices arranged above the TSVs.

### BRIEF DESCRIPTION OF THE DRAWINGS

FIG. 1 depicts a schematic configuration of a semiconductor device in a cross-sectional view according to an embodiment of the disclosure.

FIG. 2 depicts part of a method of forming a TSV-Bump structure according to an embodiment of the disclosure.

FIG. 3 depicts part of a method of forming a TSV-Bump structure according to an embodiment of the disclosure.

FIG. 4 depicts part of a method of forming a TSV-Bump structure according to an embodiment of the disclosure.

FIG. 5 depicts part of a method of forming a TSV-Bump structure according to an embodiment of the disclosure.

FIG. 6 depicts part of a method of forming a TSV-Bump structure according to an embodiment of the disclosure.

FIG. 7 depicts a schematic configuration of a semiconductor system in a cross-sectional view according to an embodiment of the disclosure.

### DETAILED DESCRIPTION

Various example embodiments of the disclosure will be described below in detail with reference to the accompanying drawings. The following detailed descriptions refer to the accompanying drawings that show, by way of illustration, specific aspects in which embodiments of the disclosure may be practiced. These embodiments are described in sufficient detail to enable those skilled in the art to practice the disclosure. Other embodiments may be utilized, and structure, logical and electrical changes may be made without departing from the scope of the disclosure. The various embodiments disclosed herein are not necessary mutually exclusive, as some disclosed embodiments can be combined with one or more other disclosed embodiments to form new embodiments.

In the descriptions, common or related elements and elements that are substantially the same are denoted with the same signs, and the descriptions thereof may be reduced or omitted. In the drawings, the dimensions and dimensional ratios of each unit do not necessarily match the actual dimensions and dimensional ratios in the embodiments.

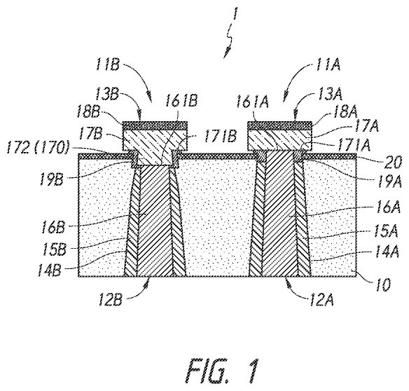

FIG. 1 depicts an example of a schematic configuration of a semiconductor device 1 in a cross-sectional view according to an embodiment of the disclosure. The semiconductor device 1 includes a semiconductor substrate 10 and a plurality of TSV-Bump structures 11A and 11B. The semiconductor substrate 10 may be a silicon (Si) wafer or die. The semiconductor substrate 10 may be a layer of Si, such as a silicon epitaxial layer. The semiconductor substrate 10 contains single-crystal silicon, for example.

The TSV-Bump structures 11A and 11B are provided to the semiconductor substrate 10 and include, respectively, TSVs 12A and 12B and bumps 13A and 13B. A number of TSV-Bump 11A and 11B structures provided to the semiconductor substrate 10 is not limited to that shown in the drawing. The TSVs 12A and 12B are provided inside respective holes (or openings) 14A and 14B formed extending in a vertical direction in the semiconductor substrate 10. Such holes may be referred to as via holes. Herein, the vertical direction refers to a top and bottom direction in the case where a back surface of the semiconductor device 1 or the semiconductor substrate 10 is disposed at bottom as depicted in the drawings. The via holes 14A and 14B may be formed by etching the semiconductor substrate 10. The etching may be performed by, for example, Bosch process. Bosch process includes isotropic etching of a semiconductor substrate to form a hole using an etching gas and deposition of a protective film on an inner side wall and an inner bottom wall of the hole using a deposition gas, and alternately repeats the etching process and the deposition process until the hole of a predetermined size is achieved.

In the via holes 14A and 14B, the TSVs 12A and 12B include, respectively, insulating films 15A and 15B and conductive films 16A and 16B. The insulating films 15A and 15B are provided on respective inner walls of the via holes 14A and 14B. The insulating films 15A and 15B may be dielectric layers forming liners between the semiconductor substrate 10 and the conductive films 16A and 16B to provide electrical isolation to the surrounding semiconductor substrate 10. Each of the insulating films 15A and 15B may be an oxide layer, a nitride layer, or a combination thereof. Silicon dioxide (SiO₂) or silicon nitride (Si₃N₄) may be used, for example. The insulating films 15A and 15B may be formed by, for example, depositing borophosphosilicate glass (BPSG) or spin-on glass (SOG) on the entirety of the inner walls of the via holes 14A and 14B. The thus-formed insulating films 15A and 15B have holes (or openings) each with substantially the same shape as or a similar shape to that of the via holes 14A and 14B.

The conductive films 16A and 16B are provided in the openings of the insulating films 15A and 15B, respectively. The conductive films 16A and 16B provide conductive portions of the TSVs 12A and 12B. The conductive films 16A and 16B contain a conductive material, such as copper (Cu). The conductive material fills the openings of the insulating films 15A and 15B. Each of the conductive films 16A and 16B has a columnar shape. Each of the TSVs 12A and 12B has a cylindrical shape with tapered or slanted side walls toward an upper portion thereof in the vertical direction. Both conductive films 16A and 16B protrude or project from the upper portions of the respective TSVs 12A and 12B. The amount of protrusion or projection of the conductive film 16A is greater than that of the conductive film 16B. The protrusion portion (may also be referred to as projection portion) of the conductive film 16A extends and is exposed above a surface of the semiconductor substrate 10. The protruding portion of the conductive film 16B protrudes at least from the upper surface of the insulating film 15B but remains below the surface of the semiconductor substrate 10. The amount of the protrusion may depend on predetermined specifications required for each of the respective TSVs 12A and 12B (or TSV-Bump structures 11A and 11B) according to, for example, their applications to a certain semiconductor system including a plurality of stacked semiconductor devices, such as memory devices.

In the TSV-Bump structures 11A and 11B, the bumps 13A and 13B are provided on the semiconductor substrate 10 at positions corresponding to the conductive films 16A and 16B. The bumps 13A and 13B include conductive plugs (may also be referred to as conductive plug portions) 17A and 17B and conductive pads (may also be referred to as conductive pad portions) 18A and 18B, each of which contains a conductive material, such as metal or metal alloy including for example, copper (Cu), tin (Sn), nickel (Ni), silver (Ag), etc. The conductive plugs 17A and 17B and the conductive pads 18A and 18B form main bodies and upper surface portions of the bumps 13A and 13B. The conductive pads 18A and 18B cover entirety of or at least substantial part of upper surfaces of the conductive plugs 17A and 17B.

The conductive plugs 17A and 17B are electrically coupled to the conductive films 16A and 16B of the TSVs 12A and 12B. The conductive plug 17A has a flat bottom surface 171A, and at least part of the bottom surface 171A is in contact with an upper surface 161A of the protruding portion of the conductive film 16A. The contacting part or position is above the surface of the semiconductor substrate 10. The conductive plug 17B has a bottom sub-portion 172 under a bottom surface 171B. The bottom sub-portion 172 may be formed narrower in width than the bottom surface 171B of the conductive plug 17B. The bottom sub-portion 172 may be formed shorter in height than the conductive plug 17B. The bottom sub-portion 172 protrudes downwardly from the bottom surface 171B of the conductive plug 17B. At least part of the bottom sub-portion 172 is buried in a portion or an opening of the semiconductor substrate 10. In one instance, a substantial part of the bottom sub-portion 172 may be buried in the opening formed in the semiconductor substrate 10. In another instance, the entirety of the bottom sub-portion 172 may be buried in the opening formed in the semiconductor substrate 10. The bottom sub-portion 172 contacts an upper surface 161B of the protruding portion of the conductive film 16B. The contacting part or position between the bottom sub-portion 172 and the conductive film 16B is below the surface of the semiconductor substrate 10 and in the opening of the semiconductor substrate 10. Through the bottom sub-portion 172, conductive paths are formed between the conductive films 16A and 16B of the TSVs 12A and 12B and the conductive plugs 17A and 17B of the bumps 13A and 13B, respectively. The bumps 13A and 13B provide electrical connection between the TSV-Bump structures 11A and 11B and contact electrodes, wirings, or the like of another semiconductor device (not separately depicted) stacked on the semiconductor device 1.

There are also provided insulating films 19A and 19B between the TSVs 12A and 12B and the bumps 13A and 13B. The insulating film 19A is substantially embedded in a space between an upper surface of the insulating film 15A of the TSV 12A and the bottom surface 171A of the conductive plug 17A of the bump 13A. The insulating film 19A surrounds at least an outer side surface of the protruding portion of the conductive film 16A of the TSV 12A. The insulating film 19B is substantially embedded in a space between an upper surface of the insulating film 15B of the TSV 12B and the bottom surface 171B of the conductive plug 17B of the bump 13B. The insulating film 19B surrounds at least an outer side surface of the protruding portion of the conductive film 16B of the TSV 12B. The insulating film 19B also surrounds an outer side surface and part of a bottom surface of the bottom sub-portion 172 of the conductive plug 17B. The insulating films 19A and 19B provide electrical isolation to the surrounding silicon substrate 10 at connecting areas between the conductive films 16A and 16B of the TSVs 12A and 12B and the conductive plugs 17A and 17B of the bumps 13A and 13B.

Further, there is provided an insulating film (or a protective film) 20 on an upper surface of the semiconductor substrate 10 in areas where the TSV-Bump structures 11A and 11B are not provided. The insulating film 19 may be an oxide layer, a nitride layer, or a combination thereof.

As shown in FIG. 1, in the TSV-Bump structure 11B of the present embodiment, the conductive film 16B of the TSV 12B is formed deeper from the surface of the semiconductor substrate 10. The upper surface 161B of the conductive film 16B is lower than the surface of the semiconductor substrate 10 and in the opening of the semiconductor substrate 10. As described above, the conductive plug 17B of the bump 13B has the bottom sub-portion 172 under the bottom surface 171B. This bottom sub-portion 172 provides a step structure (may also be referred to as a step structure portion) 170. In the example, in a cross-sectional view, at least side surfaces of the bottom sub-portion 172 protruding or extending downwardly from the bottom surface 171B and a bottom surface of the bottom sub-portion 172 between the side surfaces form an outer step-shape of the step structure 170. In the example, the side surfaces are slightly slanted in a vertical direction and the bottom surface is flat or substantially flat in a horizontal direction in the drawing. The step structure 170 is also conductive, and is integral with the conductive plug 17B. The step structure 170 and the conductive plug 17B together form the bump 13B in an integral manner or as a single whole. The step structure 170, or at least part of the step structure 170, is in the opening of the semiconductor substrate 10. The opening of the semiconductor substrate 10 is provided in an area where the conductive plug 17B meets and contacts the conductive film 16B. This area is where at least part of the conductive path is formed between the conductive plug 17B and the conductive film 16B. The step structure 170 is configured to couple the conductive film 16B of the TSV 12B and the conductive plug 17B of the bump 13B with each other. The step structure 170 provides further stable connection between the TSV 12B and the bump 13B in the TSV-Bump structure 11B. Since the step structure 170 is provided in the opening of the semiconductor substrate 10 and also surrounded by the insulating film 19B, the step structure 170 remains unexposed to the outside of the semiconductor substrate 10 and hence provides further stable electrically coupling between the conductive film 16B and the conductive plug 18B and achieves a more reliable TSV-Bump structure.

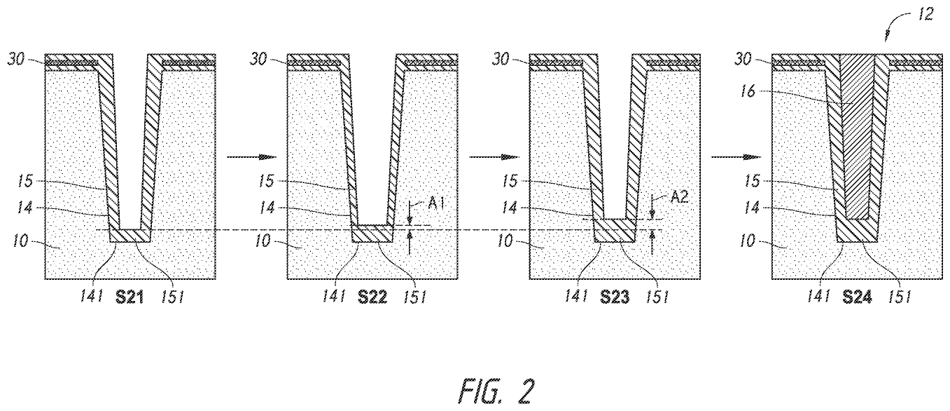

FIGS. 2-5 depict an example of a method of forming the TSV-Bump structures 11A and 11B of the semiconductor device 1 according to an embodiment of the disclosure.

FIG. 2 depicts an example of forming a TSV 12 according to the present embodiment. TSV 12 in FIG. 2 includes a via hole 14 formed in the semiconductor substrate 10, an insulating film 15 formed on an inner wall of the via hole 14, and a conductive film 16 in an opening of the insulating film 15. The via hole 14, the insulating film 15, and the conductive film 16 correspond to the via holes 14A and 14B, the insulating films 15A and 15B, and the conductive films 16A and 16B in the example of FIG. 1, respectively.

As shown in FIG. 2, first, the via hole 14 is formed in the semiconductor substrate 10, and the insulating film 15 is provided on the inner side and bottom walls of the via hole 14 (S21). In the example, the via hole 14 has a tapered or slanted sidewall toward a bottom surface 141 thereof, and the insulating film 15 has a tapered sidewall formed along the tapered sidewall of the via hole 14. A portion of the insulating film 15 on an upper surface of the semiconductor substrate 10 may include a portion called blok 30. The blok 30 is a film to prevent diffusion of a metal material, such as Cu, used for the conductive film 16 of the TSV 12. The blok 30 may be formed of, for example, silicon carbon nitride (SiCN). The blok 30 may be provided by plasma chemical vapor deposition.

The semiconductor substrate 10 may be a silicon (Si) wafer or die. The semiconductor substrate 10 may be a layer of Si, such as a silicon epitaxial layer. The semiconductor substrate 10 contains single-crystal silicon, for example.

As in the case with the via holes 14A and 14B, the via hole 14 may be formed by etching a portion of the semiconductor substrate 10. The etching may be performed by, for example, Bosch process that alternately repeats isotropic etching of the semiconductor substrate 10 to form a hole using an etching gas, such as sulfur hexafluoride (SF₆) gas, and deposition of a protective film on inner side and bottom walls of the hole using a deposition gas, such as octafluorocyclobutane (C₄F₈) gas. Once Bosch cycle includes the etching and the deposition, and multiple Bosch cycles are repeated. This alternating process or the multiple Bosch cycles gradually digs the via hole 14 until a certain depth is achieved in the semiconductor substrate 10. Bosch process is one example, and other processes, such as reactive ion etching (RIE) using inductively coupled plasma (ICP), may be used to form the via hole 14 as appropriate. The tapered sidewall of the via hole 14 can be formed by adjusting conditions of Bosch process or other etching processes in an appropriate manner.

As in the case with the insulating films 15A and 15B, the insulating film 15 may be a dielectric layer forming a liner between the silicon substrate 10 and a conductive film of the TSV to be formed at a later stage. The insulating film 15 may be an oxide layer, a nitride layer, or a combination thereof. Silicon dioxide (SiO₂) or silicon nitride (Si₃N₄) may be used, for example. The insulating film 15 may be formed by, for example, depositing BPSG, SOG, or other appropriate materials.

After formation of the via hole 14 and the insulating film 15, annealing is applied to the insulating film 15 to cause at least part of the insulating film 15, such as a side wall thereof, to melt and slide downwards to a bottom portion 151 of the insulating film 15 (S22). This causes a certain amount of the material of the insulating film 15 to accumulate at the bottom portion 151 and increases a thickness of the bottom portion 151. A1 in FIG. 2 indicates a difference in thickness between the pre-anneal, initial bottom portion 151 (S21) and the post-anneal bottom portion 151 (S22). To achieve a predetermined thickness, anneal conditions including but not limited to temperature and time are adjusted in an appropriate manner. The conditions may be set to achieve the predetermined thickness of the bottom portion 151 while maintaining a predetermined thickness of the sidewall portion of the insulating film 15 so as not to expose the underlying sidewall of the via hole 14.

Subsequently, to even further increase the thickness of the bottom portion 151 of the insulating film 15, deposition of a supplemental or additional insulating film may be applied to the already-formed insulating film 15 (S23). The additional insulating film may be a supplemental or additional spacer. The deposition of the additional insulating film may be performed using the same material as that of the already-formed insulating film 15. A2 in FIG. 2 indicates a difference in thickness between the initial bottom portion 151 (S21) and the final bottom portion 151 (S23). While further increasing the thickness of the bottom portion 151, this process may also increase the thickness of the sidewall portion of the insulating film 15 to a predetermined level as needed.

In a case where a diameter of a TSV becomes smaller, an aspect ratio of the TSV becomes higher. The higher aspect ratio might cause some difficulty in filling a hole with a conductive material by plating to form a conductive film of the TSV. The processes of forming the TSV according to the present embodiment can increase the thickness of the insulating film 15 at the bottom of the via hole 14 to lower the aspect ratio of the TSV. This facilitates the conductive material burying process into the hole or opening of the insulating film 15. In the present embodiment, the insulating film 15 may have a relatively strong reflow property to further the increase of the bottom thickness by the annealing process.

Finally, the opening of the insulating film 15 is filled with a conductive material, such as Cu, to form the conductive film (or the conductive portion) 16 (S24). The TSV 12 with the thus-formed conductive film 16 undergoes some post processes, such as a backside grinding process and a backside etchback process, to have a final shape and structure, which correspond to the TSVs 12A and 12B in the example of FIG. 1.

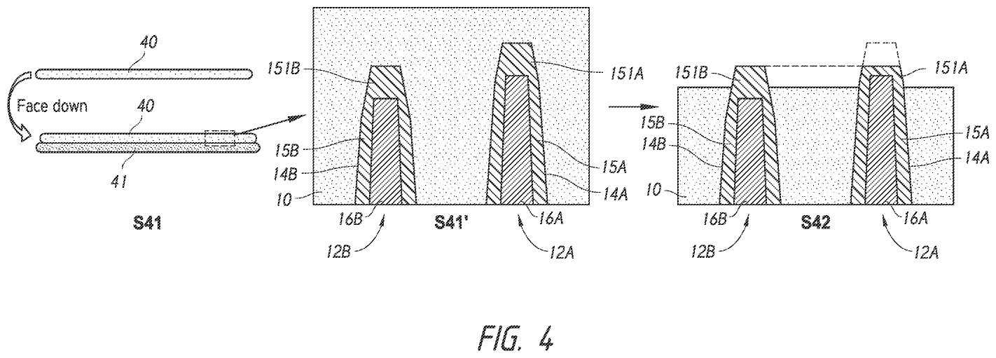

According to the present embodiment, the thickness of the bottom portion 151 of the insulating film 15 is increased by the annealing (S23) and, as appropriate, the additional deposition (S24). The thickness is sufficiently increased that the conductive film 16 remains within the insulating film 15 during at least the etchback process (see FIG. 4). That is, even if the etchback process is performed, the conductive film 16 is not exposed to the outside of the insulating film 15 but remains covered and protected by the insulating film 15. Therefore, the annealing (23) and, as appropriate, the additional deposition (S24) are performed under such conditions that the resulting bottom portion 151 of the insulating film 15 has the thickness which can maintain the coverage and protection of the conductive film 16A by the insulating film 15 during the etchback process.

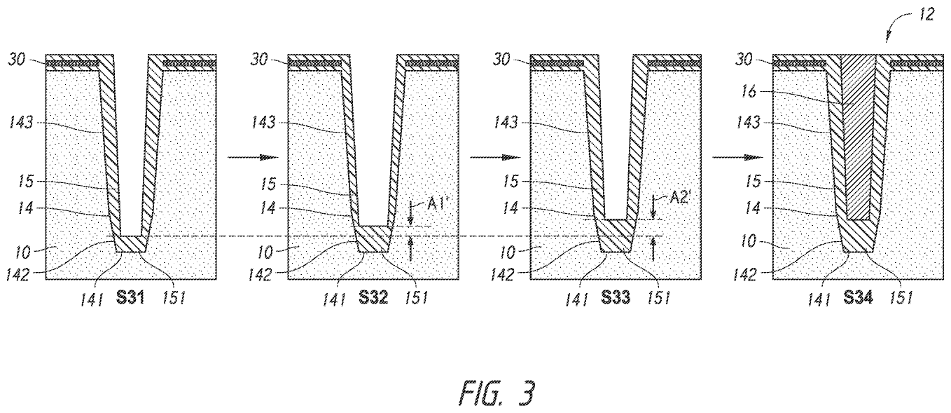

FIG. 3 depicts another example of forming the TSV 12 according to the present embodiment. As shown in FIG. 3, the via hole 14 is formed in the semiconductor substrate 10, and the insulating film 15 is formed on the inner side and bottom surfaces of the via hole 14 (S31). In the example of FIG. 3, a bottom (or lower) portion 142 of the via hole 14 is formed narrower than that of the via hole 14 in the example of FIG. 2 (S31). A sidewall of the bottom portion 142 is more tapered or slanted towards the bottom surface 141 than a portion (may also be referred to as a side portion or an upper portion) 143 above the bottom portion 142. The sidewall of the bottom portion 142 has a greater taper angle than that of the side portion 143. The closer the tapered sidewall of the bottom portion 142 is to the bottom surface 141, the smaller the diameter of the bottom portion 142 is. The via hole 14 thus has a two-step tapered shape with the bottom portion 142 and the side or upper portion 143 having the different taper angles from one another. In the example of FIG. 3, the bottom portion 142 of the via hole 14 may also be formed deeper in the semiconductor substrate 10 than that of the via hole 14 in the example of FIG. 2.

In the case of isotropic etching by Bosch process using SF₆ as an etching gas and C₄F₈ as a protective film deposition gas, process conditions to form the further tapered bottom portion 142 of the via hole 14 may include, for example: bias voltage in the range of 250-300 V during the first Bosch cycle to the range of 200-230 V during the second Bosch cycle; and gas flow rate in the range of 450-550 sccm during the first Bosch cycle to the range of 600-700 sccm during the second Bosch cycle for SF₆ and gas flow rate in the range of 300-400 sccm during the first Bosch cycle to the range of 190-290 sccm during the second Bosch cycle for C₄F₈. The conditions of the first Bosch cycle are for forming the side or upper portion 143 of the via hole 14, and the conditions of the second Bosch cycle following the first Bosch cycle are for forming the bottom portion 142 of the via hole 14, thereby providing the two-step tapered shape of the via hole 14. Further, in the case of the deposition process of BPSG or SOG, process conditions to form the insulating film 15 on the sidewall and bottom of the via hole 14 may include, for example: deposition amount in the range of 50-200 nm; and heat treatment temperature in the range of 200-600° in Celsius. If multiple via holes 14 are to be formed to provide multiple TSVs 12 in the semiconductor substrate 10, the process conditions of forming the via holes 14, such as Bosch process, may be adjusted as appropriate. The thus-formed via holes 14 may have different depths in the semiconductor substrate 10 from one another, resulting in the multiple TSVs 12 with various depths in the same semiconductor substrate 10.

Subsequently, in a similar manner to the processes (S22, S23) in FIG. 2, annealing (S32) and additional deposition (S33) are applied to increase the thickness of the bottom portion 151 of the insulating film 15. Since the bottom portion 151 is formed narrower or further tapered, if the same amount of the insulating film 15 as that of the insulating film 15 in the example of FIG. 2 is melted by annealing, the thickness or the height from the bottom surface 141 of the via hole 14 becomes greater than that of the example of FIG. 2. In FIG. 3, A1′ and A2′ indicate, respectively, a difference in thickness between the pre-anneal, initial bottom portion 151 (S31) and the post-anneal bottom portion 151 (S32) and a difference in thickness between the initial bottom portion 151 (S31) and the final bottom portion 151 (S33). Both A1′ and A2′ in FIG. 3 are greater than A1 and A2 in FIG. 2. As one example of process conditions, for the additional deposition (S33), tetraethyl orthosilicate (TEOS) of 400-600 nm is deposited. The resulting thickness of the bottom portion 151 of the insulating film 15 may be, for example, in the range of 0.5-2.0 um.

Finally, the conductive film 16 is embedded in the opening of the insulating film 15 (S34). The conductive film 16 in the example of FIG. 3 may have a different depth or vertical length from the conductive film 16 in the example of FIG. 2 due to, for example, the difference in the thickness of the bottom portion 151 of the insulating film 15 between the two examples, resulting in various sizes of the TSV 12.

FIG. 4 depicts an example of forming the TSV 12 (12A, 12B) following the processing in FIG. 3 according to the present embodiment. Once a predetermined number of the TSVs 12, each of which including at least the via hole 14, the insulating film 15 and the conductive film 16, are formed in the semiconductor substrate 10, a wafer 40 including the semiconductor substrate 10 goes through a backside grinding process. Subsequently, the semiconductor substrate 10 is turned upside down for the next processing. For example, the wafer 40 including the semiconductor substrate 10 is flipped to face down on a support wafer 41 (S41/S41′). A backside surface of the wafer 40 is now facing upward. The bottom portion 151 of the insulating film 15 shown in FIG. 3 is now a top portion of the insulating film 15. For ease of description herein, the top portion 151 (post-wafer flip) uses the same reference number as the bottom portion 151 (pre-wafer flip). The example of FIG. 4 shows the TSVs 12A and 12B including the via holes 14A and 14B, the insulating films 15A and 15B, and the conductive films 16A and 16B. In the example, the TSVs 12A and 12B have a different height (or depth) in the semiconductor substrate 10 from one another. The height of the TSV12A is greater than that of the TSV12B. The via hole 14A of the TSV12A was formed by etching the corresponding portion of the semiconductor substrate 10 deeper than the via hole 14B of the TSV 12B in the same semiconductor substrate 10, resulting in the difference in depth or height in the semiconductor substrate 10.

Subsequently, the flipped wafer 40 goes through a backside etchback process (S42) to remove an upper portion (that is a lower portion prior to the wafer flip) of the semiconductor substrate 10. During this process, the top portions 151A and 151B (that are the bottom portions prior to the wafer flip) of the TSVs 12A and 12B are exposed and projects above the semiconductor substrate 10 whose surface height has been decreased due to the upper portion removal. Further, since the top portion 151A of the insulating film 15A has the greater thickness than that of the top portion 151B of the insulating film 15B, the etchback process removes a part of the top portion 151A (see the dotted trapezoid in the drawing to show the removed part). Upper surfaces of the top portions 151A and 151B may have the same height level with each other from the upper surface of the semiconductor substrate 10 after the etchback process (see the dotted horizontal line). The resulting top portion 151A may have the same thickness as the top portion 151B. Also, the conductive film 16A of the TSV 12A within the top portion 151A protrudes or projects above the upper surface of the semiconductor substrate 10, whereas the conductive film 16B of the TSV 12B stays buried below the upper surface of the semiconductor substrate 10.

In the present embodiment, since the thickness of the top portion 151A has been increased by the previous processes including the annealing (S22, S32) and, as appropriate, the additional deposition (S23, S33), the conductive film 16A remains within the top portion 151A of the insulating film 15A. That is, even after the etchback process, the conductive film 16A is not exposed to the outside of the insulating film 15A but remains covered and protected by the insulating film 15A. This effectively reduces a possibility of contamination of the conductive film 16A which might have been caused if the conductive film 16A were exposed outside of the insulating film 15A. Hence, occurrence of defective TSVs is mitigated and the yield ratio of good, satisfactory TSVs increases.

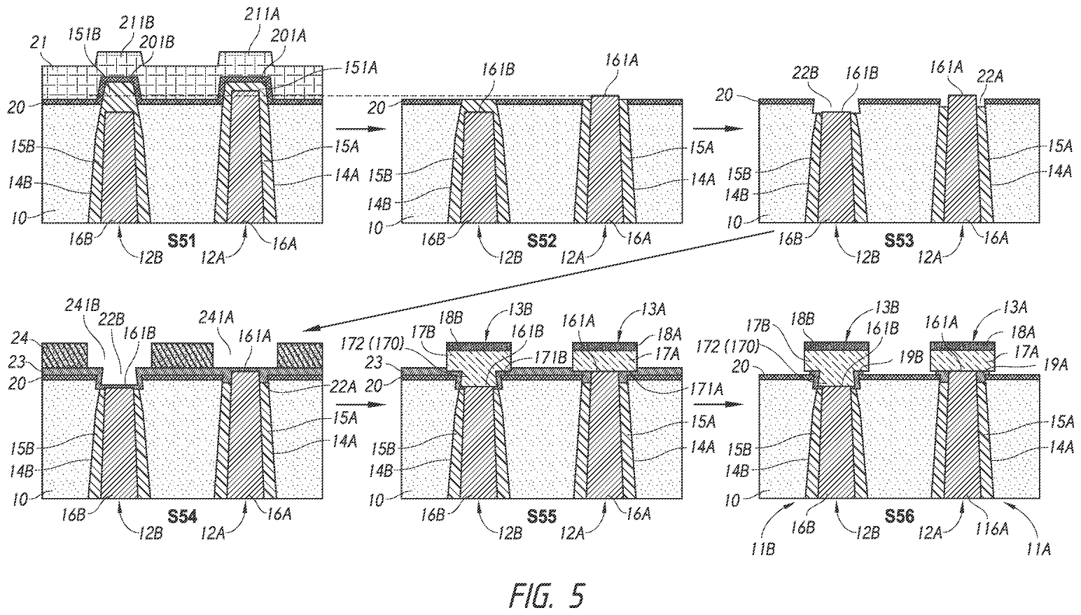

FIG. 5 depicts an example of forming the bumps 13A and 13B and the TSV-Bump structures 11A and 11B following the processing shown in FIG. 4 according to the present embodiment. As shown in FIG. 5, after the formation of the TSVs 12A and 12B, the insulating film 20 is formed on the semiconductor substrate 10 to cover the surface of the semiconductor substrate 10 and the top portions 151A and 151B of the insulating films 15A and 15B exposed above the semiconductor substrate 10 (S51). The insulating film 20 may be formed by, for example, chemical vapor deposition (CVD). The insulating film 20 may be, for example, a silicon nitride (SiN) film or any other film of an appropriate insulating material. On the insulating film 20, an oxide film 21 is also deposited (S51). The insulating film 20 and the oxide film 21 have projecting parts 201A, 201B, 211A, 211B covering the top portions 151A and 151B of the insulating films 15A and 15B.

A planarization process is then applied to make a substantially flat upper surface (S52). The planarization may be performed by, for example, chemical mechanical polishing (CMP). Other polishing techniques may be applicable as appropriate. The planarization removes the entirety of the oxide film 21 and the projecting parts 201A and 201B of the insulating film 20 above its flat portion. At least some of the top portions 151A and 151B of the insulating films 15A and 15B that are above the flat surface of the insulating film 20 are also removed. Furthermore, the protruding portion of the conductive film 16A within the top portion 151A is removed together with the top portion 151A (see the dotted horizontal line). The conductive film 16A may have an upper surface 161A exposed and slightly projected above the surrounding flat surface. An upper surface 161B of the conductive film 16B remains unexposed within the insulating film 15B.

Next, an etching process is performed to remove upper portions of the insulating films 15A and 15B (S53). This etching may be either wet etching or dry etching. By this removal, openings 22A and 22B below the upper surface of the semiconductor substrate 10 are formed for both TSVs 12A and 12B, and the top portions of the conductive films 16A and 16B are exposed within the openings 22A and 22B. The etching is performed under conditions where an etching rate of the insulating films 15A and 15B is higher than that of the insulating film 20 so that the insulating film 20 remains on the semiconductor substrate 10. The etching is performed until the upper portions of the insulating films 15A and 15B are removed to form the openings 22A and 22B each having a predetermined depth.

On the exposed surfaces after the etching process, another insulating film 23 is deposited (S54). The insulating film 23 covers the exposed flat surface of the insulating film 20, the exposed surfaces of the openings 22A and 22B, and the exposed surfaces of the conductive films 16A and 16B including at least the upper surfaces 161A and 161B. In the example, the insulating film 23 entirely fills the opening 22A on the TSV 12A, while it leaves the opening 22B on the TSV 12B. Then, a layer of photoresist 24 is deposited on an upper surface of the insulating film 23, and openings 241A and 241B are formed in the photoresist layer 24 at positions corresponding to the underlying TSVs 12A and 12B by photolithography (S54).

In the openings 241A and 241B, the bumps 13A and 13B are provided by forming the conductive plugs 17A and 17B and the conductive pads 18A and 18B (S55). The conductive plugs 17A and 17B may be formed by plating using conductive materials, such as metal or metal alloy. The conductive pads 18A and 18B are added on the upper surfaces of the conductive plugs 17A and 17B, respectively, by also plating or by other appropriate processes. The remaining photoresist layer 24 is then removed. During the plating process of the conductive plug 17B, since the opening 241B includes the opening 22B or at least has substantially the same shape as the opening 22B whose inner surfaces are surrounded by the insulating film 23 (see S54), the bottom sub-portion 172 is formed in the opening 22B, extending from the bottom surface 171B of the conductive plug 17B, substantially filing the opening 22B, and contacting the upper surface 161B of the conductive film 16B (see S55). A bottom surface of the bottom sub-portion 172 may penetrate into the underlying insulating film 23 for a certain amount to contact the upper surface 161B of the conductive film 16B. The thus-formed bottom sub-portion 172 provides the step structure 170 in the area where the conductive plug 17B meets and contacts the conductive film 16B (see also FIG. 1). As for the conductive plug 17A, its bottom surface 171A penetrates into the insulating film 23 for a certain amount and contacts the upper surface 161A of the conductive film 16A.

Finally, by another etching process, an exposed part or layer of the insulating film 23 on the flat surface of the underlying insulating film 20 around the conductive plugs 17A and 17B of the bumps 13A and 13B is removed (S56). The etching is performed under conditions where the etch rate of the insulating film 23 is higher than the etch rate of the insulating film 20 so that only the exposed parts of the insulating film 23 are removed. The etching is performed until the upper surface of the insulating film 20 is exposed. The remaining parts of the insulating film 23 are substantially unexposed under the bottom surfaces 171A and 171B of the conductive plugs 17A and 17B and surrounding the bottom sub-portion 172 of the conductive plug 17B. These remaining parts form the insulating films 19A and 19B between the TSVs 12A and 12B and the bumps 13A and 13B (see also FIG. 1). The thus-formed TSVs 12A and 12B and bumps 13A and 13B form the TSV-Bump structures 11A and 11B of the present embodiment, respectively.

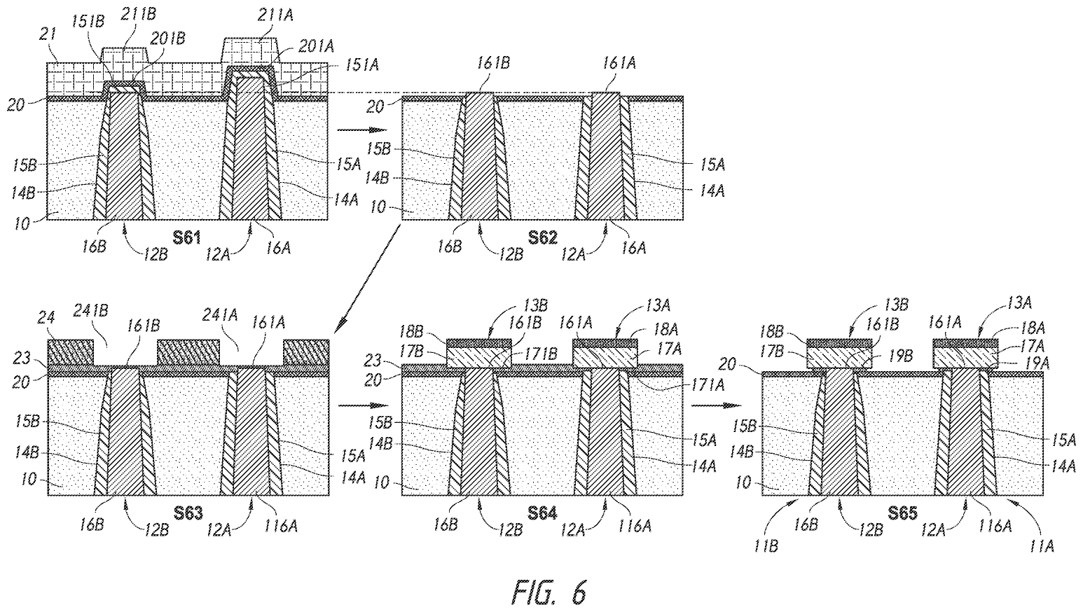

FIG. 6 depicts another example of forming the bumps 13A and 13B and the TSV-Bump structures 11A and 11B according to the present embodiment. In the example of FIG. 6, the TSVs 12A and 12B (S61) have different sizes from those of the TSVs 12A and 12B in the example of FIG. 5 (S51). For example, the TSV 12A has both the top portion 151A of the insulating film 15 and the conductive film 16A inside the insulating film 15 project higher above the upper surface of the semiconductor substrate 10 than those in FIG. 5. Consequently, the projecting parts 201A and 211A of the insulating film 20 and the oxide film 21 over the top portion 151A also project more than those in FIG. 5. Further, for example, the conductive film 16B within the insulating film 15B of the TSV 12B is formed higher than that in FIG. 5. These differences between FIG. 5 and FIG. 6 are due to, for example, differences in conditions of the processing shown in FIGS. 2 and 3 and/or the processing shown in FIG. 4. For example, during the processing in FIGS. 2 and 3, the via hole 14 may be formed deeper in the semiconductor substrate 10, and/or the opening of the insulating film 15 may be formed deeper inside the via hole 14, and/or the conductive film 16 may be formed deeper inside the insulating film 15. For example, during the processing in FIG. 4, the backside etchback process may be performed to remove the substrate and/or the top portions (the bottom portions before the wafer flip) 151A and 151B of the insulating films 15A and 15B to a lesser extent. Accordingly, by adjusting the conditions of the relevant processes, the size of each of the resulting TSVs 16, 16A and 16B can be changed as needed or as appropriate. Besides the size differences, the insulating film 20 and the oxide film 21 in FIG. 6 are formed in a similar manner to the example in FIG. 5 (S51, S61).

In a similar manner to the example in FIG. 5 (S52), planarization is then applied to make a substantially flat upper surface (S62). In the example of FIG. 6, as with the upper surface 161A of the conductive film 16A, the conductive film 16B has its upper surface 161B exposed and slightly projected above the surrounding flat surface. The upper surfaces 161A and 161B may have the same height level with each other (see the dotted horizontal line) from the upper surface of the semiconductor substrate 10 after the etchback process. In the example of FIG. 6, as indicated by the dotted horizontal line, some of the top portion of the conductive film 16A is removed, while the top portion of the conductive film 16B remains unremoved. In a case where the top portion of the conductive film 16B is formed higher, some of the top portion of the conductive film 16B may also be removed, as with the top portion of the conductive film 16A.

Next, unlike the example in FIG. 5, the processing in the example of FIG. 6 moves to deposition of the insulating film 23 (S63) without the extra etching process (S53 in FIG. 5). This is because the upper surface 161B of the conductive film 16B is already exposed above the insulating film 15B and there is no need to further etch the insulating film 15B. The insulating film 23 covers the exposed flat surface of the insulating film 20, the exposed upper surfaces of the insulating films 15A and 15B, and the exposed upper surfaces 161A and 161B of the conductive films 16A and 16. Then, the photoresist layer 24 is deposited on the insulating film 23, and openings 241A and 241B are formed in the photoresist layer 24 at positions corresponding to the underlying TSVs 12A and 12B by photolithography (S63).

In a similar manner to the example in FIG. 5 (S55), in the openings 241A and 241B, the conductive plugs 17A and 17B and the conductive pads 18A and 18B are provided by plating or other appropriate methods to form the bumps 13A and 13B (S64). The remaining photoresist layer 24 is then removed. Unlike the example in FIG. 5, both the bottom surfaces 171A and 171B of the conductive plugs 17A and 17B remain substantially flat, penetrates into the insulating film 23 for a certain depth, and meets and contacts the upper surfaces 161A and 161B of the conductive films 16A and 16B.

Finally, in a similar manner to the example in FIG. 5 (S56), another etching process is performed under the conditions where the etch rate of the insulating film 23 is higher than the etch rate of the insulating film 20 so that only the exposed parts of the insulating film 23 are removed (S65). The remaining parts of the insulating film 23 form the insulating films 19A and 19B between the TSVs 12A and 12B and the bumps 13A and 13B (see also FIG. 1). The thus-formed TSVs 12A and 12B and bumps 13A and 13B form the TSV-Bump structures 11A and 11B of the present embodiment, respectively.

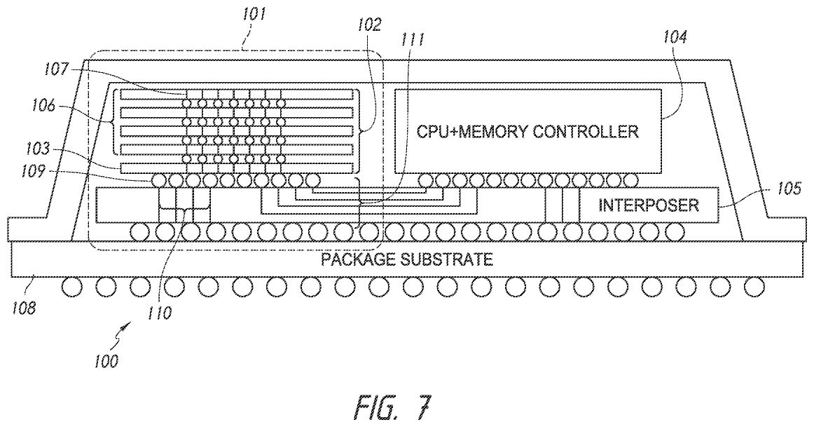

FIG. 7 depicts an example of a schematic configuration of a semiconductor system 100 in a cross-sectional view according to an embodiment of the disclosure. The semiconductor system 100 includes an apparatus, which is a semiconductor memory device 101 in an embodiment of the disclosure. The semiconductor memory device 101 is one example of the semiconductor device 1 or at least part of the semiconductor device 1. The semiconductor system 100 may also include a central processing unit (CPU) and memory controller 104, which may be a controller chip, on an interposer 105 on a package substrate 108. The interposer 105 may include one or more power lines 110 which may supply power supply voltage from the package substrate 108. The interposer 105 may include a plurality of channels 111 that may interconnect the CPU and memory controller 104 and the semiconductor memory device 101. For example, the semiconductor memory device 101 may be a dynamic random access memory (DRAM). The memory controller 104 may provide a clock signal, a command signal, and may further transmit and receive data signals. The plurality of channels 111 may transmit the data signals between the memory controller and the semiconductor memory device 101. The semiconductor memory device 101 may include a plurality of chips 102 including an interface (I/F) chip 103 and a plurality of memory core chips 106 stacked with each other. A number of the memory core chips 106 may not be limited to 4 and may be more or fewer as appropriate. Each of the memory core chips 106 may include a plurality of memory cells and circuitries accessing the memory cells. For example, the memory cells may be dynamic random access memory (DRAM) memory cells. The semiconductor memory device 101 may include conductive vias 107 (such as the TSVs 12A and 12B of the TSA-Bump structures 11A and 11B) which couple the OF chip 103 and the memory core chips 106 by penetrating the OF chip 103 and the memory core chips 106. The OF chip 103 may be coupled to the interposer 105 via interconnects 109 (such as the bumps 13A and 13B of the TSA-Bump structures 11A and 11B). For example, the interconnects 109 may be microbumps having bump pitches of less than about or less than one hundred micrometers and exposed on an outside of the OF chip 103. A portion of each of the interconnects 109 may be coupled to the one or more power lines 110. Another portion of each of the interconnects 109 may be coupled to one or more of the channels 111.

DRAM is merely one example of the semiconductor memory device 101 or the semiconductor device 1, and the embodiments and the above descriptions thereof are not intended to be limited to DRAM. Memory devices other than DRAM, such as a static random-access memory (SRAM), a flash memory, an erasable programmable read-only memory (EPROM), a magnetoresistive random-access memory (MRAM), and a phase-change memory, can also be applied as the semiconductor memory device 101 or the semiconductor device 1. Furthermore, devices other than memory, including logic ICs, such as a microprocessor and an application-specific integrated circuit (ASIC), are also applicable as the semiconductor device according to the present embodiments.

Although various embodiments of the disclosure have been described in detail, it will be understood by those skilled in the art that embodiments of the disclosure may extend beyond the specifically described embodiments to other alternative embodiments and/or uses and modifications and equivalents thereof. In addition, other modifications which are within the scope of the disclosure will be readily apparent to those of skill in the art based on the described embodiments. It is also contemplated that various combination or sub-combination of the specific features and aspects of the embodiments may be made and still fall within the scope of the disclosure. It should be understood that various features and aspects of the embodiments can be combined with or substituted for one another in order to form varying mode of the embodiments. Thus, it is intended that the scope of the disclosure should not be limited by the particular embodiments described above.

What is claimed is:

1. A through-silicon via (TSV)-Bump structure, comprising:
a TSV in a semiconductor substrate; and
a bump on the TSV, wherein
the bump includes a conductive plug portion and a step structure portion under the conductive plug portion, and
the step structure portion is configured to electrically couple the TSV and the conductive plug portion with each other.

2. The TSV-Bump structure according to claim 1, wherein
the conductive plug portion is above a surface of the semiconductor substrate, and
at least part of the step structure portion is in an opening of the semiconductor substrate.

3. The TSV-Bump structure according to claim 2, wherein the step structure portion electrically couples the bump to the TSV in the opening.

4. The TSV-Bump structure according to claim 1, wherein the step structure portion is narrower in width than the conductive plug portion.

5. The TSV-Bump structure according to claim 1, wherein the step structure portion is conductive, and is integral with the conductive plug portion.

6. The TSV-Bump structure according to claim 1, wherein at least part of the step structure portion is surrounded by an insulating film, the insulating film configured to provide insulation to the step structure portion at least from the surrounding semiconductor substrate.

7. The TSV-Bump structure according to claim 1, wherein the step structure portion electrically couples the bump to an exposed upper surface of a conductive film of the TSV to provide an electrical path between the bump and the conductive film of the TSV.

8. A semiconductor device, comprising:
a semiconductor substrate; and
a through-silicon via (TSV)-Bump structure comprising:
a through-silicon via (TSV) in the semiconductor substrate; and
a bump on the TSV, wherein
the bump includes a conductive plug portion and a step structure portion under the conductive plug portion, and
the step structure portion is configured to electrically couple the TSV and the conductive plug portion with each other.

9. The semiconductor device according to claim 8, wherein
the conductive plug portion is above a surface of the semiconductor substrate, and
at least part of the step structure portion is in an opening of the semiconductor substrate.

10. The semiconductor device according to claim 9, wherein the step structure portion is configured to electrically couple the bump to the TSV in the opening.

11. The semiconductor device according to claim 8, wherein the step structure portion is narrower in width than the conductive plug portion.

12. The semiconductor device according to claim 8, wherein the step structure portion is conductive, and is integral with the conductive plug portion.

13. The semiconductor device according to claim 8, wherein at least part of the step structure portion is surrounded by an insulating film, the insulating film configured to provide insulation to the step structure portion at least from the surrounding semiconductor substrate.

14. The semiconductor device according to claim 8, wherein the step structure portion electrically couples the bump to an exposed upper surface of a conductive film of the TSV to provide an electrical path between the bump and the conductive film of the TSV.

15. A method of forming a through-silicon via (TSV)-Bump structure, the method comprising:
forming a via hole in a semiconductor substrate, the via hole including at least a first bottom portion;
depositing an insulating film to the via hole, the insulating film including at least a second bottom portion over the first bottom portion of the via hole;
performing annealing to cause at least part of the insulating film to melt and slide downwards and accumulate at the second bottom portion to increase a thickness of the second bottom portion;
providing a conductive film to an opening of the insulating film to form a TSV; and
providing a bump on the TSV to form the TSV-Bump structure.

16. The method according to claim 15, further comprising:
depositing an additional insulating film to further increase the thickness of the second bottom portion.

17. The method according to claim 15, further comprising:
forming the via hole to have a side wall thereof tapered toward the first bottom portion; and
making the first bottom portion further tapered than the side wall.

18. The method according to claim 17, wherein a first taper angle of the first bottom portion is greater than a second taper angle of the side wall.

19. The method according to claim 15, further comprising:
turning upside down the semiconductor substrate including the TSV; and
performing an etchback process to the semiconductor substrate to remove at least part of the semiconductor substrate and at least part of the insulating film, wherein
at least another part of the insulating film is exposed above a surface of the semiconductor substrate while covering the conductive film in the insulating film.

20. The method according to claim 15, further comprising:
etching the insulating film to provide an opening in the semiconductor substrate where an upper surface of the conductive film is exposed above an upper surface of the insulating film; and
providing at least part of the bump on the exposed upper surface of the conductive film in the opening to electrically couple the bump to the conductive film.
